(19) United States
(12) Patent Application Publication
(10) Pub. No.: US 2025/0331347 A1
(43) Pub. Date: Oct. 23, 2025

(54) OPTOELECTRONIC DEVICE

(71) Applicant: UNIKORN SEMICONDUCTOR CORPORATION, Hsinchu (TW)

(72) Inventors: Chia-Hao Chang, Hsinchu (TW); Shih-I Chen, Hsinchu (TW); Chun-Ming Wu, Hsinchu (TW); Yu-Hsien Li, Hsinchu (TW)

(21) Appl. No.: 18/640,671

(22) Filed: Apr. 19, 2024

(51) Int. Cl. H01L 27/15

(52) U.S. Cl. CPC H10H 29/142

(57) ABSTRACT

The present disclosure provides an optoelectronic device. The device includes: a substrate having a periphery; and a semiconductor stack disposed on the substrate. The semiconductor stack includes a first light emitting unit, and a second light emitting unit located closer to the periphery than the first light emitting unit to the periphery. The first light emitting unit includes a first light emitting stack and a first conductive structure directly contacting the first light emitting stack with a first contact length, and the second light emitting unit includes a second light emitting stack and a second conductive structure directly contacting the second light emitting stack with a second contact length. The second contact length is larger than the first contact length.

### BACKGROUND OF THE INVENTION

### Field of the Invention

The present disclosure relates to semiconductor technology, and, in particular, to an optoelectronic device.

### Description of the Related Art

With the development of electronic devices, each component in an electronic device is gradually being scaled down. However, the reduction in the size of electronic devices such as optoelectronic devices greatly increases the difficulty of the manufacturing process, leading to problems such as a decrease in yield. Therefore, although existing optoelectronic devices are generally adequate for their intended use, they have not been entirely satisfactory in all respects. Therefore, there are still some issues to be addressed regarding optoelectronic device.

### BRIEF SUMMARY OF THE INVENTION

An embodiment of the present disclosure provides an optoelectronic device. The device includes: a substrate having a periphery; and a semiconductor stack disposed on the substrate. The semiconductor stack includes a first light emitting unit, and a second light emitting unit located closer to the periphery than the first light emitting unit to the periphery. The first light emitting unit includes a first light emitting stack and a first conductive structure directly contacting the first light emitting stack with a first contact length, and the second light emitting unit includes a second light emitting stack and a second conductive structure directly contacting the second light emitting stack with a second contact length. The second contact length is larger than the first contact length.

An embodiment of the present disclosure provides an optoelectronic device. The device includes: a substrate comprising a periphery and a semiconductor stack disposed on the substrate. The semiconductor stack includes a first light emitting unit and a second light emitting unit located closer to the periphery than the first light emitting unit to the periphery. The first light emitting unit includes a first light emitting stack and a first conductive structure, and the second light emitting unit includes a second light emitting stack and a second conductive structure. The first conductive structure includes a first metal layer directly contacting the first light emitting stack, and the second conductive structure includes a second metal layer and a first conductive layer disposed between the second metal layer and the second light emitting stack.

An embodiment of the present disclosure provides an optoelectronic device. The device includes: a semiconductor stack including a plurality of first light emitting units located in the central region, and one of the plurality of first light emitting units including a first light emitting stack and a central conductive layer on the first light emitting stack; a plurality of second light emitting units surrounding the plurality of first light emitting units. Each of the plurality of second light emitting units includes a second light emitting stack and a first conductive layer on the second light emitting stack. The widths of the first conductive layers increases radially from the central region toward the periphery.

### BRIEF DESCRIPTION OF THE DRAWINGS

The present disclosure can be more fully understood by reading the subsequent detailed description and examples with references made to the accompanying drawings. It is noted that, in accordance with the standard practice in the industry, various features are not drawn to scale and are merely used for illustration. In fact, the dimensions of the various components may be arbitrarily increased or reduced to clearly represent the features of the embodiments of the present disclosure. In the accompanying drawings:

FIGS. 1A, 2A and 3A show cross-sectional views of optoelectronic devices, in accordance with some embodiments of the present disclosure;

FIGS. 1B, 2B, 2C, 3B and 4 show top views of optoelectronic devices, in accordance with some embodiments of the present disclosure; and

FIGS. 5 to 12 show cross-sectional views during various stages of forming an optoelectronic device, in accordance with some embodiments of the present disclosure.

### DETAILED DESCRIPTION OF THE INVENTION

The following disclosure provides many different embodiments, or examples, for implementing different components of the provided subject matter. Specific examples of components and arrangements are described below to simplify the illustration of the present disclosure. These are, of course, merely examples and are not intended to limit the present disclosure. For example, the formation of a first component over or on a second component in the description that follows may include embodiments in which the first and second components are formed in direct contact, and may also include embodiments in which additional components may be formed between the first and second components, such that the first and second components may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “over,” “on,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The component may be otherwise oriented (rotated 90 degrees or at other orientations) and the spatially relative descriptors used herein may likewise be interpreted accordingly.

Forming method of some embodiments of the present disclosure are described. In these embodiments, additional operations can be provided before, during, and/or after the stages described. Some of the stages that are described can be replaced or eliminated for different embodiments. Additional components can be added to the semiconductor component structure. Some of the components described below can be replaced or eliminated for different embodiments. Although some embodiments are discussed with operations performed in a particular order, these operations may be performed in another logical order.

In the existing optoelectronic device, such as vertical cavity surface emitting laser (VCSEL) array with multiple light-emitting apertures, it has been observed that the brightness near the center of an optoelectronic device may be lower than the brightness in the edge of the optoelectronic device, leading to a larger far field divergence angle of the optoelectronic device. Furthermore, it has been observed that a light-emitting aperture positioned near bonding region at the edge of an optoelectronic device may have higher brightness compared to another light-emitting aperture positioned near the central region of the optoelectronic device. This disparity results in unsatisfactory near-field uniformity of the optoelectronic device. This problem is considered to be related to the fact that the current crowds near the edge, where a bonding region located, of the optoelectronic device.

To address the abovementioned issues, an optoelectronic device having a conductive structure is provided by embodiments of the present disclosure. In some embodiments, an uniform light emission and an improved far field divergence angle in a VCSEL array can be achieved by disposing the conductive structure to broaden the current conducting range. Furthermore, an improved brightness uniformity of the overall optoelectronic device can be achieved. Consequently, in some embodiments, the present disclosure can alleviate the abovementioned problems by selectively disposing a conductive structure in some light-emitting aperture of the optoelectronic device.

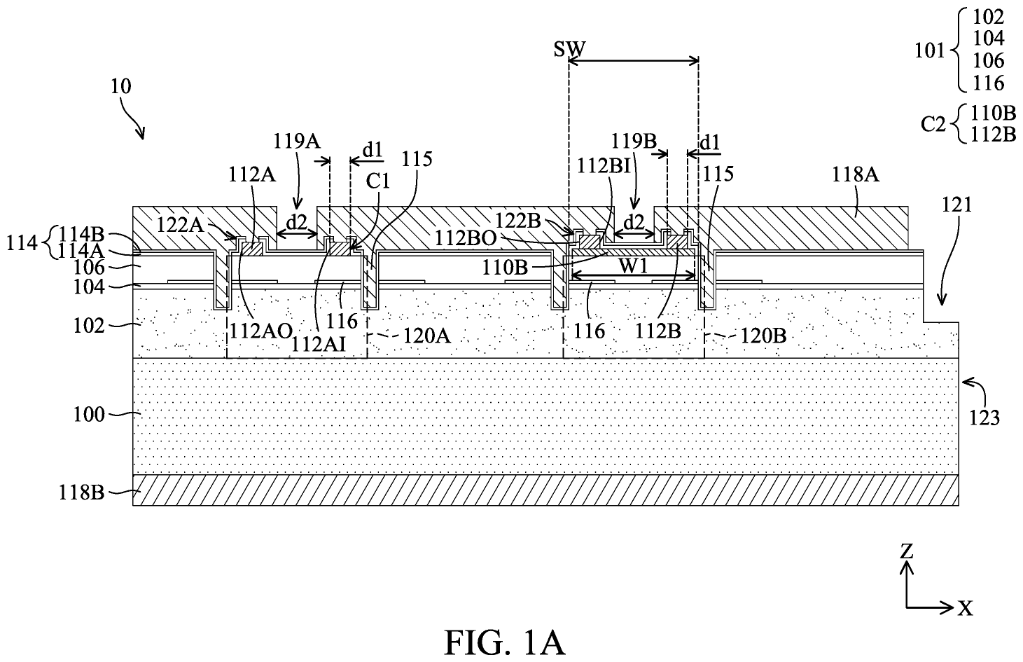

FIG. 1A shows a cross-sectional view of an optoelectronic device 10 taken along line A-A′ in FIG. 1B, in accordance with an embodiment of the present disclosure. As shown in FIG. 1A, the optoelectronic device 10 includes a substrate 100 having a periphery 123 and a semiconductor stack 101 over the substrate 100. The semiconductor stack 101 sequentially includes, from bottom to top, a first semiconductor structure 102, an active region 104, and a second semiconductor structure 106. In some embodiments, the semiconductor stack 101 may optionally further include a current confinement structure 116 between the active region 104 and the first semiconductor structure 102, or between the active region 104 and the second semiconductor structure 106. The current confinement structure 116 can restrict the direction of current, thereby improving the performance of optoelectronic device 10. The optoelectronic device 10 may include an insulating structure 114 on the semiconductor stack 101. In the embodiment, the insulating structure 114 includes a first insulating layer 114A and optionally includes a second insulating layer 114B on the first insulating layer 114A. In the embodiment, the optoelectronic device 10 further optionally includes an aisle 121.

Referring to FIGS. 1A-1B, the optoelectronic device 10 includes a first light emitting unit 122A and a second light emitting unit 122B, and the second light emitting unit 122B is located closer to the periphery 123 of the substrate 100 than the first light emitting unit 122A is. In the embodiment shown in FIG. 1B, the optoelectronic device 10 includes a plurality of first light emitting units 122A (such as four first light emitting units 122A) and a plurality of second light emitting units 122B (such as twelve second light emitting units 122B) surrounding the plurality of first light emitting units 122A. The optoelectronic device 10 may include more light emitting units, the number of the light emitting units shown in FIG. 1A-1B is merely for illustrative purpose.

Each of the plurality of first light emitting units 122A includes a first light emitting stack 120A and a first conductive structure C1 on the first light emitting stack 120A, and each of the plurality of second light emitting units 122B includes a second light emitting stack 120B and a second conductive structure C2 on the second light emitting stack 120B. The first conductive structure C1 directly and electrically contacts the first light emitting stack 120A with a first contact length L1, and the second conductive structure C2 directly and electrically contacts the second light emitting stack 120B with a second contact length L2 larger than the first contact length L1.

In the embodiment, the optoelectronic device 10 is VCSEL, and the first light emitting unit 122A and the second light emitting unit 122B are able to emit coherent light. In the embodiment, the optoelectronic device 10 further includes a plurality of trenches 115 surrounding the plurality of first light emitting units 122A and the plurality of second light emitting units 122B as shown FIGS. 1A and 1B. More specifically, each of the plurality of first light emitting stacks 120A is surrounded by one of the plurality of trenches 115. Each of the plurality of second light emitting stacks 120B is surrounded by one of the plurality of trenches 115. Each of the first light emitting stacks 120A and the second light emitting stacks 120B includes a stack width SW. In the embodiment, the stack widths SW of the first light emitting stacks 120A and the stack widths SW of the second light emitting stacks 120B are the same. In other embodiment, the stack widths SW of the first light emitting stacks 120A are different from the stack widths SW of the second light emitting stacks 120B.

In the embodiment, the first conductive structure C1 includes a first metal layer 112A. The second conductive structure C2 includes a first conductive layer 110B and optionally includes a second metal layer 112B.

As shown in FIG. 1A, the first metal layer 112A includes an outer wall 112AO and an inner wall 112AI, and the distance between the outer wall 112AO and the inner wall 112AI is defined as the first metal width d1. The second metal layer 112B includes an outer wall 112BO and an inner wall 112BI, the distance between the outer wall 112BO and the inner wall 112BI is defined as the first metal width d1, that is the second metal layer 112B and the first metal layer 112A have the same width a. The first conductive layer 110B includes a first conduction width W1. The first contact length L1 is defined as and equals to two times of the first metal width d1, and the second contact length L2 is defined as and equals to the first conduction width W1. In one embodiment, the first metal width d1 is greater than or equal to 2 μm and smaller than 4 μm. Because the current may crowd near the periphery 123, the brightness of the light emitted from the second light emitting unit 122B may be higher leading to an unsatisfactory near field uniformity of the optoelectronic device 10. By virtue of the first conductive layer 110B disposed on the second light emitting stack 120B, the brightness of the light emitted from the second light emitting unit 122B can be reduced, thereby improving the overall brightness uniformity of the optoelectronic device 10. Furthermore, the first conductive layer 110B is transparent and has a transparency to the light emitted by the second light emitting stack 120B, and the transparency is between 80% and 92%, which may partially block the emission light. Therefore, the brightness of the second light emitting unit 122B with the first conductive layer 110B is approximately the same as the brightness of the first light emitting unit 122A which does not have the first conductive layer 110B thereon, and a more uniform light emission of the optoelectronic device 10 can be achieved.

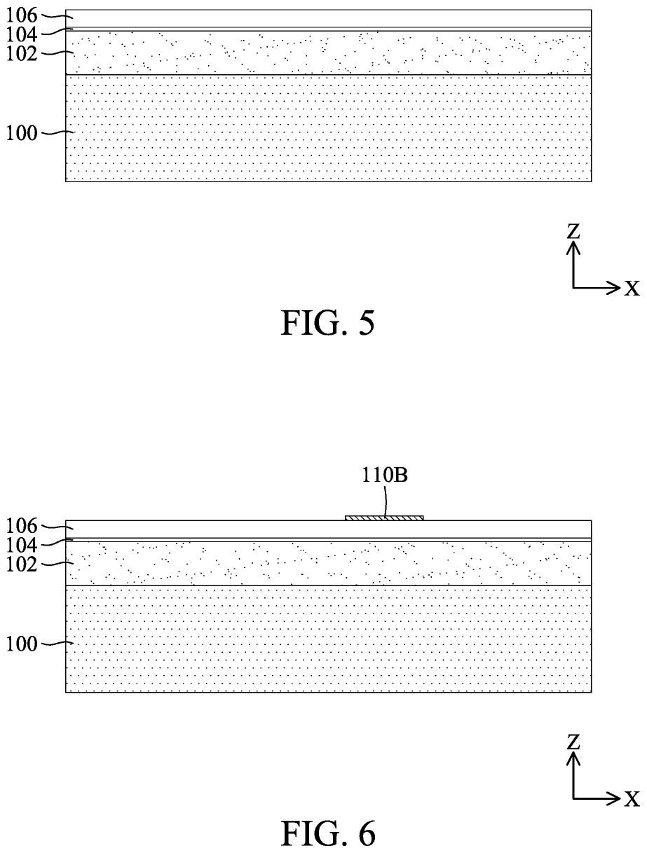

In the embodiment, the second metal layer 112B is electrically connected to the first conductive layer 110B. The first conductive layer 110B may overlap with the second metal layer 112B in the vertical direction (such as along the Z direction). In some embodiments, an overlapped width between the second metal layer 112B and the first conductive layer 110B is greater than or equal to two times of the first metal width d1, that is, the overlapped width is greater than or equal to 4 μm and smaller than 8 μm. In some embodiments, the first conduction width W1 of the first conductive layer 110B is smaller than or equal to the stack width SW of the second light emitting stack 120B. As shown in FIG. 1A, the first conduction width W1 of the first conductive layer 110B is less than the stack width SW of the second light emitting stack 120B. In some embodiments, the second light emitting stack 120B may include a top surface with a first surface area, and the first conductive layer 110B may include a top surface with a second surface area, and a ratio of the second surface area to the first surface area is between 34% and 76%. If the ratio is greater than 76%, the sidewalls of the first conductive layer 110B may not be protected by the first insulating layer 114A which is etched during the process for forming the trenches 115 (referring to FIG. 9), leading to the risk of leakage. On the other hand, if the ratio is less than 34%, the contact between the first conductive layer 110B and the second metal layer 112B may be insufficient to provide a desired conductivity.

The optoelectronic device 10 further includes a first electrode layer 118A on the semiconductor stack 101 and a second electrode layer 118B beneath the substrate 100. The first electrode layer 118A includes a plurality of first openings 119A and a plurality of second openings 119B, and the plurality of first openings 119A corresponds to the plurality of first light emitting units 122A and the plurality of second openings 119B corresponds to the plurality of second light emitting units 122B.

Each of the plurality of first openings 119A and the plurality of second openings 119B includes an opening width d2. Each of the first light emitting stacks 120A and the second light emitting stacks 120B includes the stack width SW, and the opening width d2 is smaller than the stack width SW. In the embodiment, the opening width d2 of the first opening 119A is substantially the same with the opening width d2 of the second opening 119B. In the embodiment, the second contact length L2 is larger than the opening width d2.

FIG. 1B shows a top view of the optoelectronic device 10. The optoelectronic device 10 includes a central region CR away from the periphery 123. As shown in FIG. 1B, the plurality of first light emitting units 122A are located in the central region CR, and the plurality of second light emitting units 122B are located near the periphery 123 and surrounds the plurality of first light emitting units 122A. The periphery 123 includes a first side 123A and a second side 123B opposite to the first side 123A. As shown in FIG. 1B, the first metal layers 112A and the second metal layers 112B are ring-shaped in the top view, but the present disclosure is not limited thereto. In the embodiment, the second metal layer 112B totally disposes on the first conductive layer 110B. In other words, the second metal layer 112B includes an inner wall 112BI and an outer wall 112BO located within a periphery of the first conductive layer 110B.

Still referring to FIG. 1B, the first electrode layer 118A of the optoelectronic device 10 may include a first bonding region BR1 near the first side 123A of the periphery 123. The second light emitting unit 122B is closer to the first bonding region BR1 than the first light emitting unit 122A to the first bonding region BR1.The first bonding region BR1 is used for electrically connecting to external electrical device through wire bonding process or solder bonding process.

In some embodiments, the first semiconductor structure 102 and the second semiconductor structure 106 may include gallium nitride (GaN), gallium arsenide (GaAs), indium phosphide (InP), aluminum gallium nitride (AlGaN), indium gallium nitride (InGaN), gallium indium phosphide (GaInP), aluminum gallium arsenide (AlGaAs), or aluminum gallium indium phosphide (AlGaInP), or the like. In some embodiments, the first semiconductor structure 102 and the second semiconductor structure 106 may have opposite conductivity types. For example, the first semiconductor structure 102 may be p-type, and the second semiconductor structure 106 may be n-type. Alternatively, the first semiconductor structure 102 may be n-type, and the second semiconductor structure 106 may be p-type. In some embodiments, the first semiconductor structure 102 and the second semiconductor structure 106 may include multiple pairs of periodically alternating layers with two different refractive indexes, such as a stack of periodically alternating AlGaAs layers with a high aluminum amount and AlGaAs layers with a low aluminum amount, to form a distributed Bragg reflector (DBR). Consequently, the light emitted from the active region 104 may be reflected between the first semiconductor structure 102 and the second semiconductor structure 106 to form a coherent light.

In some embodiments, the active region 104 disposed between the first semiconductor structure 102 and the second semiconductor structure 106 may have a multiple quantum well (MQW) structure including semiconductor material. In some embodiments, the active region 104 may be formed of gallium nitride (GaN), gallium arsenide (GaAs), indium phosphide (InP), aluminum gallium nitride (AlGaN), indium gallium nitride (InGaN), gallium indium phosphide (GaInP), aluminum gallium arsenide (AlGaAs), or aluminum gallium indium phosphide (AlGaInP), or the like.

In some embodiments, the material of the first insulating layer 114A and the second insulating layers 114B may be the same or different, such as epoxy resin, polyimide (PI), polybenzoxazole (PBO), silicone resin, silicon oxide, silicon nitride, or combinations thereof. In some embodiments, the first insulating layer 114A and the second insulating layer 114B both includes silicon nitride (SiNₓ).

In some embodiments, the material of the first electrode layer 118A and the second electrode layer 118B may be the same or different, and may respectively include any suitable metal oxides, metals or alloys, such as indium tin oxide (ITO), fluorine doped tin oxide (FTO), niobium doped anatase TiO₂ (NTO), lithium-fluorine-doped tin oxide (LFTO), doped zinc oxide, Au, Ni, Ag, Ge, Cu, TiW, GeAu, BeAu, Ti, Pt, Pd.

In some embodiments, the first conductive layer 110B may include any suitable materials, such as indium tin oxide (ITO), fluorine doped tin oxide (FTO), niobium doped anatase TiO₂ (NTO), lithium-fluorine-doped tin oxide (LFTO), doped zinc oxide, or the like. In some embodiments, the transparent conductive layer may be indium tin oxide (ITO). In some embodiments, the first conductive layer 110B includes a thickness of 40 nm to 100 nm. If the thickness of the first conductive layer 110B is greater than 100 nm, the first conductive layer 110B may block more emission light, leading to the undesired reduction of the brightness of emission light. On the other hand, if the thickness of the first conductive layer 110B is less than 40 nm, the conductivity of the first conductive layer 110B may become insufficient for the optoelectronic device.

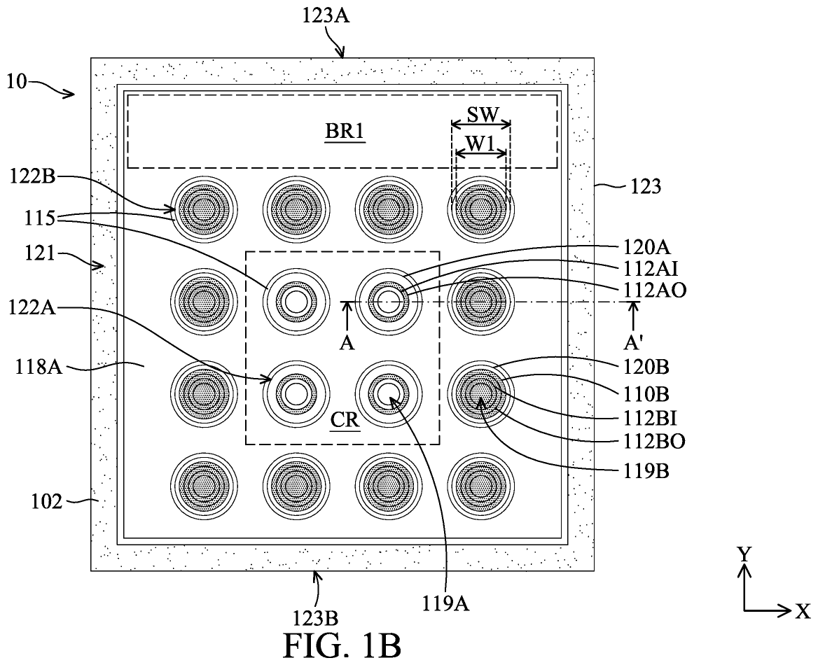

FIG. 2A shows a cross-sectional view of an optoelectronic device 20 taken along line B-B′ in FIG. 2B, in accordance with another embodiment of the present disclosure. The elements or the connections between elements of the optoelectronic device 20 are similar or the same with that of the optoelectronic device 10, the difference between the optoelectronic devices 10 and 20 is the distributions of the first conductive layer 110B. More specifically, the first conductive layer 110B may partially overlaps with the second metal layer 112B in the normal direction of the substrate 100. More specifically, the second metal layer 112B is devoid of overlapping with a part of the first conductive layer 110B and is directly connected to the second light emitting stack 120B. The second metal layer 112B directly contacts the second light emitting stack 120B with a second metal width d11. Besides, the first conduction width W1 of the first conductive layer 110B in the optoelectronic device 20 is smaller than the first conduction width W1 of the first conductive layer 110B in the optoelectronic device 10 and the second metal width d11 is smaller than the first metal width d1, and the ratio of the second metal width d11 to the first metal width d1 is larger than 0.5.

In the embodiment, the first conductive structure C1 directly and electrically contacts the first light emitting stack 120A with the first contact length L1. Likewise, the first conductive structure C1 includes the first metal layer 112A and the first contact length L1 is defined as and equals to two times of the first metal width d1.

The second conductive structure C2 directly and electrically contacts the second light emitting stack 120B with the second contact length L2.Specifically, as described aforesaid, since the second metal layer 112B and the first conductive layer 110B directly and electrically contacts the second light emitting stack 120B and the second metal layer 112B partially overlaps with the first conductive layer 110B, the second contact length L2 is defined as and equals to the sum of the first conduction width W1 and two times of the second metal width d11, that is the second contact length L2 is larger than the first conduction width W1 and small than the sum of the first conduction width W1 and two times of the first metal width d1 (W1<L2<W1+2d1). In this embodiment, the first conduction width W1 is larger than two times of the first metal width d1. It has been observed that the brightness decreases when the first conduction width W1 of the first conductive layer 110B increases, and vice versa. Therefore, the brightness of the optoelectronic device 20 may be tailored by adjusting the first conduction width W1 of the first conductive layer 110B to meet actual needs.

FIG. 2B shows a top view of the optoelectronic device 20. As shown in FIGS. 2A and 2B, the second metal layer 112B includes the outer wall 112BO and the inner wall 112BI, and the periphery of the first conductive layer 110B is between the outer wall 112BO and the inner wall 112BI. The rest features of the optoelectronic device 20 are similar to those of the optoelectronic device 10, and therefore the details will not be repeated herein for the sake of brevity.

FIG. 2C shows a top view of an optoelectronic device 30, in accordance with yet another embodiment of the present disclosure. The elements or the connections between elements of the optoelectronic device 30 are similar or the same with that of the optoelectronic device 20, the difference between the optoelectronic devices 20 and 30 is that, the optoelectronic device 30 includes a second bonding region BR2, and the first bonding region BR1 and the second bonding region BR2 are respectively located near the first side 123A and the second side 123B of the periphery 123. The central region CR locates between the first bonding region BR1 and the second bonding region BR2.

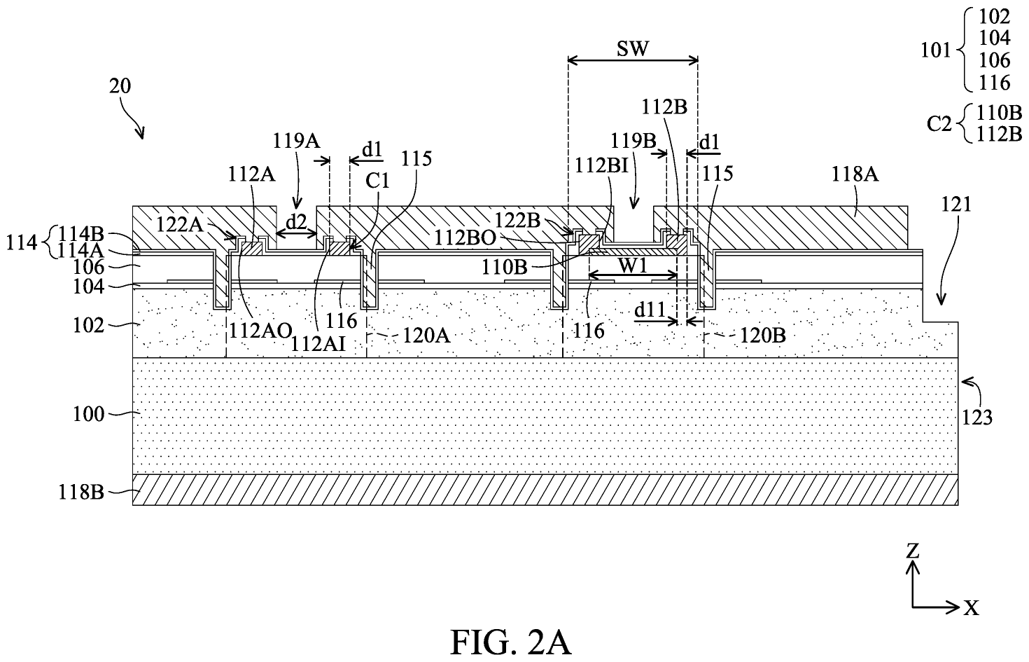

FIG. 3A shows a cross-sectional view of an optoelectronic device 40 taken along line C-C′ in FIG. 3B, in accordance with yet another embodiment of the present disclosure. The optoelectronic device 40 further includes a plurality of third light emitting units 122C located closer to the periphery 123 compared to the second light emitting units 122B, and a plurality of fourth light emitting units 122D located much closer to the periphery 123 compared to the plurality of third light emitting units 122C. In other words, the plurality of fourth light emitting units 122D are closer to the periphery 123 than other light emitting units to the periphery 123, and the plurality of first light emitting units 122A are farther from the periphery 123 than other light emitting units to the periphery 123. The plurality of second light emitting units 122B locates between the plurality of first light emitting units 122A and the plurality of fourth light emitting units 122D, and the plurality of third light emitting units 122C locates between the plurality of second light emitting units 122B and the plurality of fourth light emitting units 122D. In the embodiment, from top view of the optoelectronic device 40, as shown in FIG. 3B, the plurality of fourth light emitting units 122D surrounds the plurality of third light emitting units 122C, and the plurality of third light emitting units 122C surrounds the plurality of second light emitting units 122B.

The third light emitting unit 122C includes a third light emitting stack 120C and a third conductive structure C3 on the third light emitting stack 120C, and the fourth light emitting unit 122D includes a fourth light emitting stack 120D and a fourth conductive structure C4 on the fourth light emitting stack 120D. The third conductive structure C3 includes a third metal layer 112C and a second conductive layer 110C between the third metal layer 112C and the third light emitting stack 120C, and the fourth conductive structure C4 includes a fourth metal layer 112D and a third conductive layer 110D between the fourth metal layer 112D and the fourth light emitting stack 120D. In the optoelectronic device 40, the first conductive layer 110B of the second light emitting unit 122B has the first conduction width W1, the second conductive layer 110C of the third light emitting unit 122C has a second conduction width W2, and the third conductive layer 110D of the fourth light emitting unit 122D has a third conduction width W3. Furthermore, the second conductive layer 110C is transparent and has a transparency to the light emitted by the third light emitting stack 120C, and the transparency is between 80% and 92%, which may partially block the emission light. Similarly, the third conductive layer 110D is transparent and has a transparency to the light emitted by the fourth light emitting stack 120D, and the transparency is between 80% and 92%, which may partially block the emission light.

Since the first bonding region BR1 is located near the periphery 123 and the current injects from the first bonding region BR1, the current density in the light emitting stacks is higher near the periphery 123 than the current density in the light emitting stacks near the central region CR. Therefore, as shown in FIG. 3B, the widths of the conductive layers of the light emitting units are radially increased from the central region CR toward the periphery 123 to achieve a uniform light emission of the optoelectronic device 40. That is, in the optoelectronic device 40, the second conduction width W2 is greater than first conduction width W1 but less than the third conduction width W3 (i.e., W1<W2<W3). In other embodiments, the optoelectronic device 40 can further includes a second bonding region BR2 (referring to FIG. 2C), and the first bonding region BR1 and second bonding region BR2 are respectively located near the first side 123A and the second side 123B of the periphery 123.

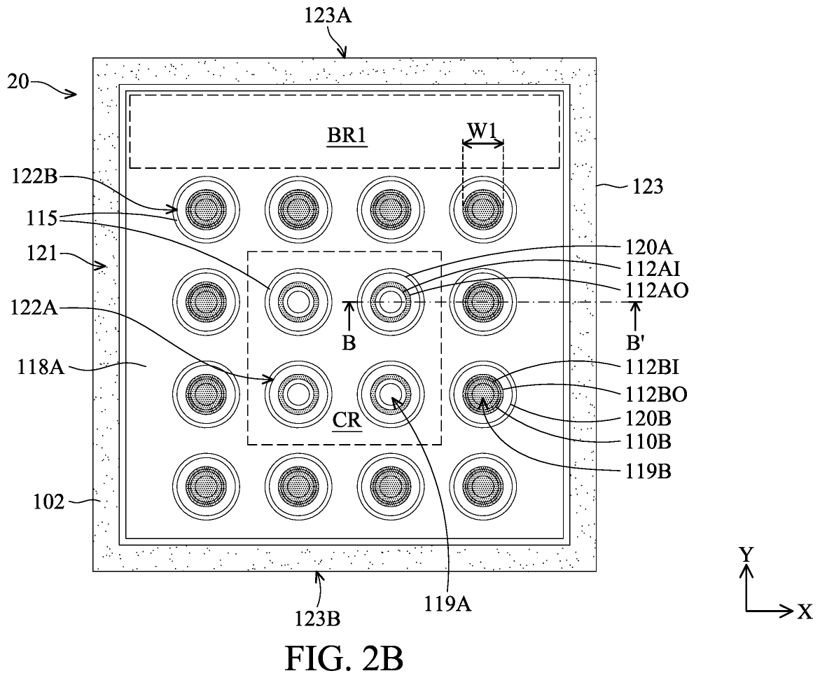

FIG. 4 shows a top view of an optoelectronic device 50 in accordance with another embodiment of the present disclosure. The elements or the connections between elements of the optoelectronic device 50 are similar or the same with that of the optoelectronic device 20, the difference between the optoelectronic devices 20 and 50 is the widths of the conductive layers. More specifically, the plurality of second light emitting units 122B surrounds the plurality of first light emitting units 122A. The plurality of second light emitting units 122B can be divided to a first group 122B1, a second group 122B2, a third group 122B3 and a fourth group 122B4. The first bonding region BR1 locates near the first side 123A of the periphery 123. The first group 122B1 of the plurality of second light emitting units 122B is closer to the first side 123A of the periphery 123, and the fourth group 122B4 of the second light emitting unit 122B is farther from the first side 123A of the periphery 123 and closer to the second side 123B of the periphery 123. The second group 122B2 locates between the first group 122B1 and the fourth group 122B4, and the third group 122B3 locates between the second group 122B2 and the fourth group 122B4.

The first group 122B1 of the plurality of second light emitting units 122B includes a second first light emitting stack 120B1 and a first first conductive layer 110B1 disposed on the second first light emitting stack 120B1. The second group 122B2 of the plurality of second light emitting units 122B includes a second second light emitting stack 120B2 and a first second conductive layer 110B2 disposed on the second second light emitting stack 120B2. The third group 122B3 of the plurality of second light emitting units 122B includes a second third light emitting stack 120B3 and a first third conductive layer 110B3 disposed on the second third light emitting stack 120B3. The fourth group 122B4 of the plurality of second light emitting units 122B includes a second fourth light emitting stack 120B4 and a first fourth conductive layer 110B4 disposed on the second fourth light emitting stack 120B4. The first first conductive layer 110B1 has a first first conduction width W_{b1}, the first second conductive layer 110B2 has a first second conduction width W_{b2}, the first third conductive layer 110B3 has a first third conduction width W_{b3}, the first fourth conductive layer 110B4 has a first fourth conduction width W_{b4}, and W_{b1}≥W_{b2}≥W_{b3}≥W_{b4}. In the embodiment, the first first conduction width W_{b1} is equal to the first second conduction width W_{b2}. The first third conduction width W_{b3} is equal to the first fourth conduction width W_{b4} and smaller than the first first conduction width W_{b1}.

In this embodiment, the first conductive structure C1 of the first light emitting unit 122A on the central region CR of the optoelectronic device 10 further includes a central conductive layer 110A on the first light emitting stack 120A. The central conductive layer 110A locates between the first light emitting stack 120A and the first metal layer 112A (see the second conductive structure C2 in FIG. 1A) and has a central conduction width Wₐ. In the embodiment, when the first conductive structure C1 includes the central conductive layer 110A, the first contact length L1 is defined as and equals to the central conduction width Wₐ, and the second contact lengths L2 of the second conductive layers 110B1˜110B4 are respectively defined as and equals to the first first conduction width W_{b1}, the first second conduction width W_{b2}, the first third conduction width W_{b3} and the first fourth conduction width W_{b4}. The first contact length L1 is smaller than the second contact length L2.

In other embodiment, similar to FIG. 1A, the first conductive structure C1 merely includes the first metal layer 112A directly contacting the first light emitting unit 122A, and there is no central conductive layer 110A on the first light emitting stack 120A.

In one embodiment, similar to the second conductive structure C2 in FIG. 2A, the central conductive layer 110A may partially overlaps with the first metal layer 112A in the normal direction of the substrate 100. More specifically, the first metal layer 112A is devoid of overlapping with a part of the central conductive layer 110A and is directly connected to the second light emitting stack 120B. In addition, the definition of the first contact length L1 can referred to the definition of the second contact length L2.

In one embodiment, some of the first light emitting unit 122A includes the central conductive layer 110A, and some of the first light emitting unit 122A does not include the central conductive layer 110A. For example, the first light emitting unit 122A, which locates in the second row of the array, closes to the first bonding region BR1 includes the central conductive layer 110A, and the first light emitting unit 122A, which locates in the third row of the array, away from the first bonding region BR1, is devoid of the central conductive layer 110A.

The first first conductive layer 110B1, the first second conductive layer 110B2, the first third conductive layer 110B3 and first fourth conductive layer 110B4 are transparent and each of them has a transparency to the light emitted by the second light emitting stack 120B, and the transparency is between 80% and 92%, which may partially block the emission light. Similarly, the central conductive layer 110A is transparent and has a transparency to the light emitted by the first light emitting stack 120A, and the transparency is between 80% and 92%.

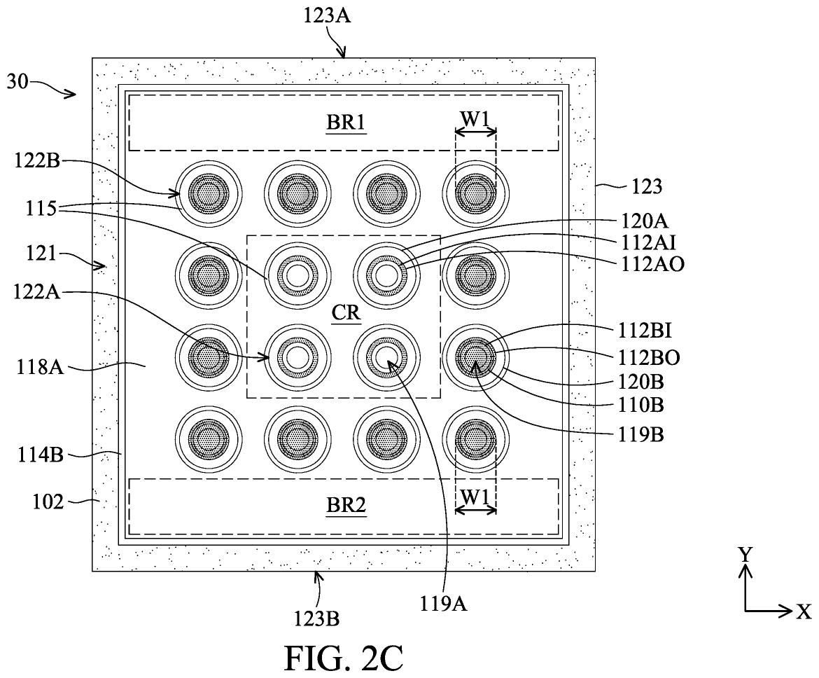

FIGS. 5 to 12 show cross-sectional views during various stages of making the optoelectronic device 10 taken along line A-A′ in FIG. 1B, in accordance with an embodiment of the present disclosure. As shown in FIG. 5, the first semiconductor structure 102, the active region 104, and the second semiconductor structure 106 are sequentially disposed on the substrate 100.

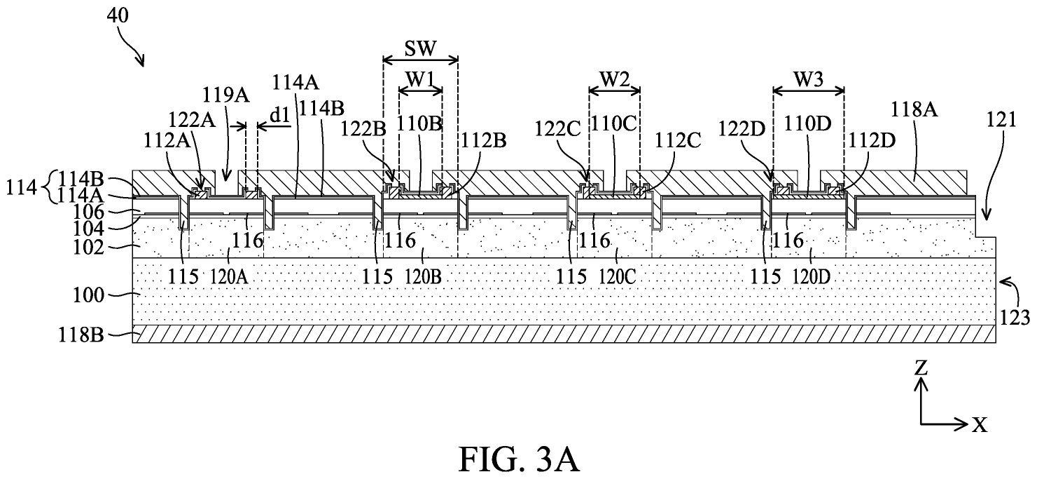

Next, referring to FIG. 6, the first conductive layer 110B is deposited on a portion of the second semiconductor structure 106.

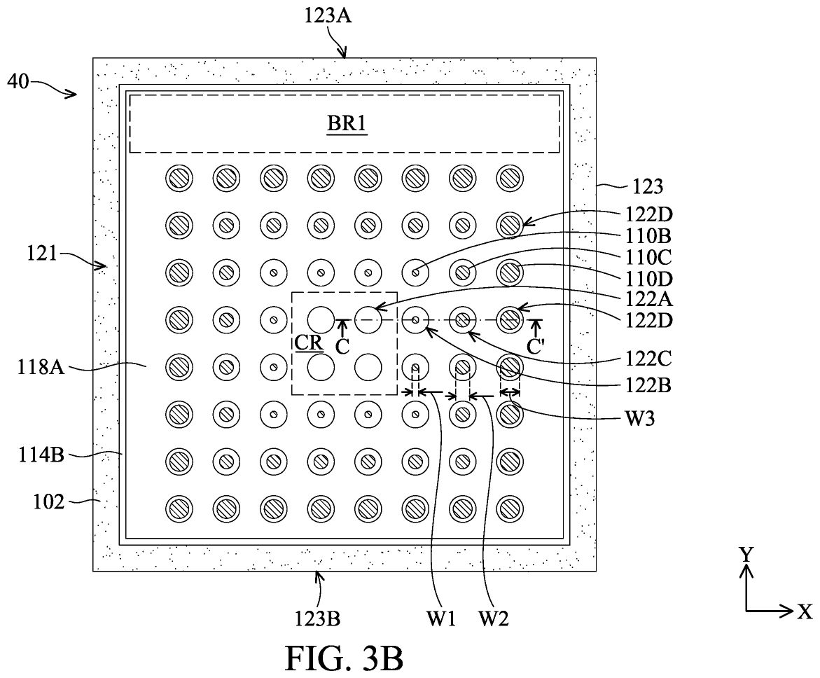

Next, referring to FIG. 7, the first metal layer 112A and the second metal layer 112B are respectively formed on the second semiconductor structure 106 and the first conductive layer 110B. The first metal layer 112A and the second metal layer 112B may be formed by PVD.

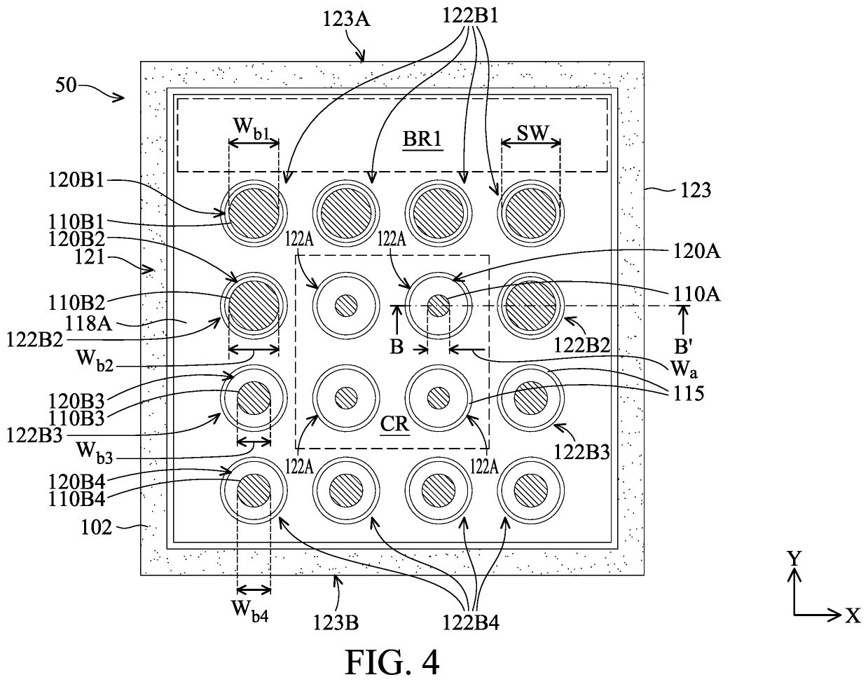

Next, referring to FIG. 8, the first insulating layer 114A is conformally formed on the second semiconductor structure 106, the first metal layer 112A, the second metal layer 112B and the first conductive layer 110B. The first insulating layer 114A may be formed by PVD, CVD, ALD, or combinations thereof.

Next, referring to FIG. 9, portions of the first insulating layer 114A, the second semiconductor structure 106, the active region 104, the first semiconductor structure 102 are removed to form the plurality of trenches 115, thereby defining the first light emitting unit 122A and the second light emitting unit 122B. The plurality of trenches 115 may be formed by dry etch, wet etch, laser drilling, or combinations thereof. Then, the current confinement structure 116 is formed between the active region 104 and the second semiconductor structure 106. The current confinement structure 116 may be formed by any suitable oxidation process, such as, a wet oxidation process.

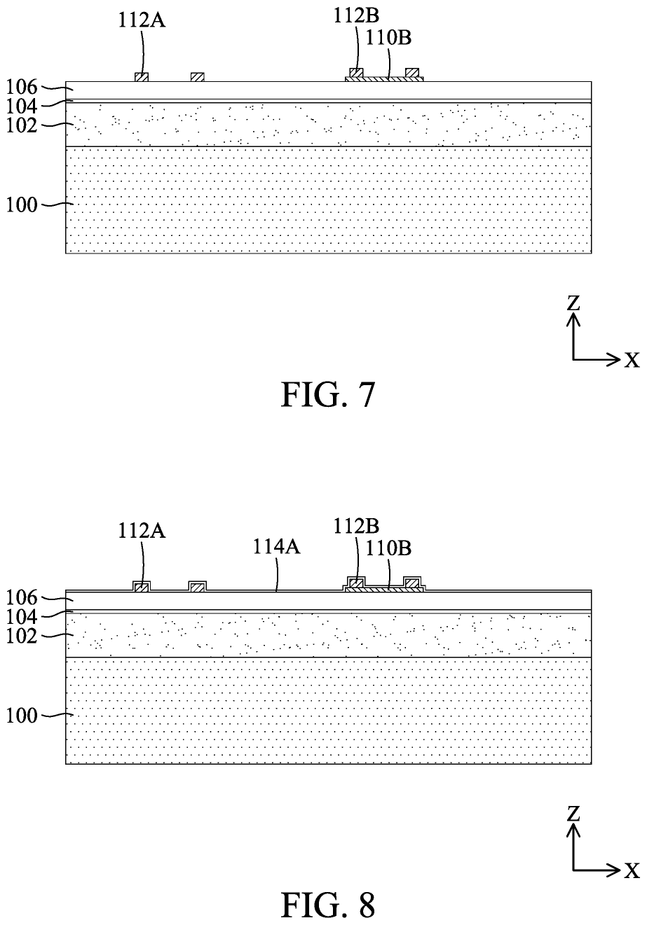

Next, referring to FIG. 10, the second insulating layer 114B is conformally formed on the structures shown in FIG. 9. The second insulating layer 114B may be formed by spin-coating, CVD or ALD. Then, portion of the first insulating layer 114A and portion of the second insulating layer 114B are etched to form a plurality of openings 117, thereby exposing a top surface of the first metal layer 112A and a top surface of the second metal layer 112B. The plurality of openings 117 may be formed by dry etch, wet etch, or combinations thereof.

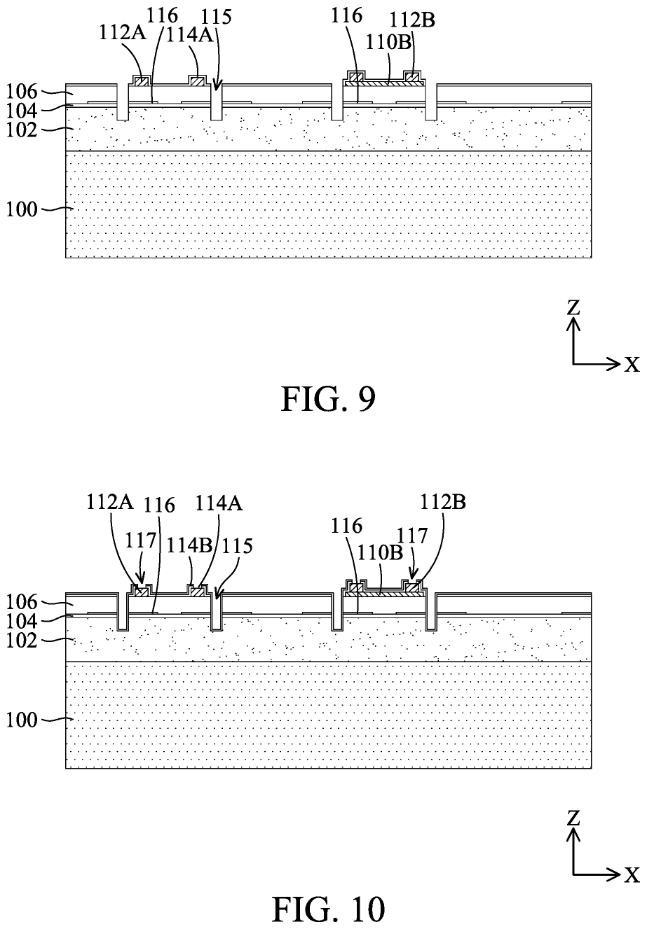

Next, referring to FIG. 11, the first electrode layer 118A may be formed on the structures shown in FIG. 10, and the first electrode layer 118A is electrically connected to the first metal layer 112A and the second metal layer 112B. Next, an etch process may be performed to form the plurality of the first openings 119A exposing portions of the first insulating layer 114A and the second insulating layer 114B located on the plurality of first light emitting stacks 120A, and the plurality of the second openings 119B exposing portions of the first insulating layer 114A and the second insulating layer 114B located on the plurality of second light emitting stacks 120B. The lights generated by the active regions 104 can be emitted toward outside from the plurality of first openings 119A and the plurality of second openings 119B. The first electrode layer 118A may be formed by any suitable process, such as PVD, and the openings 119 may be formed by wet etch, dry etch, or combinations thereof.

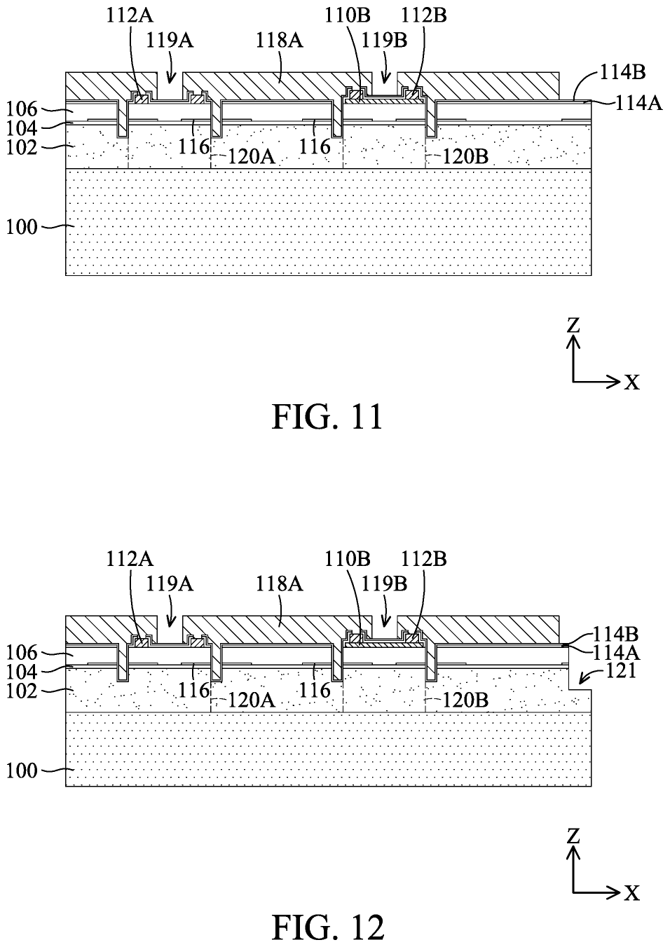

Next, referring to FIG. 12, an etch process is performed to remove portions of the first insulating layers 114A, the second insulating layer 114B, the second semiconductor structure 106, the active region 104, and the first semiconductor structure 102, thereby forming the aisle 121. The etch process may be performed by any suitable process, such as wet etch, dry etch, or combinations thereof. Next, a thinning process is performed on the substrate 100 to reduce a thickness of the substrate 100. The thinning process may be performed by a grinding process.

Finally, the second electrode layer 118B is formed below the substrate 100, and the second electrode layer 118B and the first electrode layer 118A respectively locate on the opposite sides of the semiconductor stack 101, as shown in FIG. 1A. The second electrode layer 118B may be formed by PVD.

In summary, the embodiments of the present disclosure provide an optoelectronic device having a selectively disposed conductive layer. As such, an uniform light emission may be achieved by improving the far field divergence angle and near field uniformity.

The foregoing outlines several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An optoelectronic device, comprising:
a substrate comprising a periphery; and
a semiconductor stack disposed on the substrate, wherein the semiconductor stack comprises a first light emitting unit, and a second light emitting unit located closer to the periphery than the first light emitting unit to the periphery;
wherein the first light emitting unit comprises a first light emitting stack and a first conductive structure directly contacting the first light emitting stack with a first contact length, and the second light emitting unit comprises a second light emitting stack and a second conductive structure directly contacting the second light emitting stack with a second contact length; and
wherein the second contact length is larger than the first contact length.

2. The optoelectronic device as claimed in claim 1, further comprising a first bonding region, and the second light emitting unit is closer to the first bonding region than the first light emitting unit to the bonding region.

3. The optoelectronic device as claimed in claim 1, wherein the first conductive structure comprises a first metal layer and the second conductive structure comprises a second metal layer and a first conductive layer, and the first conductive layer has a first conduction width defining the second contact length.

4. The optoelectronic device as claimed in claim 3, wherein the first conductive layer comprises a thickness of 40 nm to 100 nm.

5. The optoelectronic device as claimed in claim 3, wherein the second light emitting stack comprises a top surface with a first surface area, and the first conductive layer comprises a top surface with a second surface area, and a ratio of the second surface area to the first surface area is between 34% and 76%.

6. The optoelectronic device as claimed in claim 3, wherein the second metal layer overlaps with the first conductive layer in a normal direction of the substrate.

7. The optoelectronic device as claimed in claim 6, wherein the second metal layer overlaps with the first conductive layer in an overlapped width larger than or equal to 4 μm.

8. The optoelectronic device as claimed in claim 3, wherein the second metal layer partially overlaps with the first conductive layer in a normal direction of the substrate.

9. The optoelectronic device as claimed in claim 3, wherein the semiconductor stack further comprises a third light emitting unit located closer to the periphery of the substrate than the second light emitting unit.

10. The optoelectronic device as claimed in claim 9, wherein the third light emitting unit comprises:
a third light emitting stack; and
a third conductive structure located on the third light emitting stack and comprising a third metal layer and a second conductive layer disposed between the third metal layer and the third light emitting stack.

11. The optoelectronic device as claimed in claim 10, wherein the second conductive layer comprises a second conduction width larger than the first conduction width.

12. The optoelectronic device as claimed in claim 3, wherein the first light emitting unit further has a central conductive layer between the first metal and the first light emitting stack.

13. The optoelectronic device as claimed in claim 12, wherein the periphery has a first side and a second side opposite to the first side, and the semiconductor stack further comprises a third light emitting unit; wherein the second light emitting unit is closer to the first side and the third light emitting unit is closer to the second side.

14. The optoelectronic device as claimed in claim 13, wherein the third light emitting units comprises:
a third light emitting stack; and
a third conductive structure located on the third light emitting stack and comprising a third metal layer and a second conductive layer disposed between the third metal layer and the third light emitting stack.

15. The optoelectronic device as claimed in claim 14, wherein the central conductive layer has a central conduction width and the second conductive layer has a second conduction width, larger than the central conduction width and the first conduction width.

16. The optoelectronic device as claimed in claim 1, further comprising:
a first electrode layer disposed on the semiconductor stack, and the first electrode layer has a first opening corresponding to the first light emitting unit and a second opening corresponding to the second light emitting unit respectively, wherein the second opening comprises an opening width, and the second contact length is larger than the opening width.

17. The optoelectronic device as claimed in claim 1, wherein the first metal layer and the second metal layer have the same width.

18. The optoelectronic device as claimed in claim 1, further comprising a plurality of trenches surrounding the first light emitting unit and the second light emitting unit.

19. An optoelectronic device, comprising:
a substrate comprising a periphery; and
a semiconductor stack disposed on the substrate, wherein the semiconductor stack comprises a first light emitting unit, and a second light emitting unit located closer to the periphery than the first light emitting unit to the periphery;
wherein the first light emitting unit comprises a first light emitting stack and a first conductive structure, and the second light emitting unit comprises a second light emitting stack and a second conductive structure; and
wherein the first conductive structure comprises a first metal layer directly contacting the first light emitting stack, and the second conductive structure comprises a second metal layer and a first conductive layer disposed between the second metal layer and the second light emitting stack.

20. An optoelectronic device having a central region and a periphery, comprising:
a semiconductor stack comprising
a plurality of first light emitting units located in the central region, and one of the plurality of first light emitting units comprising a first light emitting stack and a central conductive layer on the first light emitting stack;
a plurality of second light emitting units surrounding the plurality of first light emitting units, and each of the plurality of second light emitting units comprising a second light emitting stack and a first conductive layer on the second light emitting stack;
wherein widths of the first conductive layers radially increases from the central region toward the periphery.
